(19) United States
(12) Patent Application Publication
(10) Pub. No.: US 2023/0275537 A1
(43) Pub. Date: Aug. 31, 2023

(54) Power Controller

(71) Applicant: Dometic Sweden AB, Solna (SE)

(72) Inventors: Kyle Cameron, Victoria (CA); Taylor Townsend, Victoria (CA); Sean O'Connor, Victoria (CA)

(21) Appl. No.: 18/173,516

(22) Filed: Feb. 23, 2023

Related U.S. Application Data
(60) Provisional application No. 63/314,431, filed on Feb. 27, 2022.

(51) Int. Cl. H02S 10/20; H02J 7/00; H02J 7/35; H02M 3/158; H05K 7/14; H05K 1/18; H02S 10/10; B60R 16/033

(52) U.S. Cl. CPC H02S 10/20; H02J 7/0013; H02J 7/35; H02M 3/1582; H05K 7/1427; H05K 1/18; H02S 10/10; B60R 16/033; H05K 2201/10053

(57) ABSTRACT

Present embodiments relate to a power controller for charging at least two battery banks. More specifically, the present embodiments relate to a power controller which provides for at least two input sources and may charge the at least two battery banks simultaneously or independently.

### CLAIM TO PRIORITY

This non-provisional patent application claims priority to and benefit of, under 35 U.S.C. § 119(e), U.S. Provisional Patent Application Ser. No. 63/314,431, filed Feb. 27, 2022 and titled “Power Controller”, all of which is incorporated by reference herein.

### BACKGROUND

### 1. Field of the Invention

Present embodiments relate to a power controller for charging at least two battery banks. More specifically, the present embodiments relate to a power controller which provides for at least two input sources and may charge the at least two battery banks simultaneously or independently.

### 2. Description of the Related Art

State of the art power controllers can short two batteries together in order to conduct charging. However, where battery banks are of differing types or differing voltages this shorting does not function. As a result, battery banks cannot be of mixed types.

Further, state of the art power controllers cannot use two different input sources simultaneously to charge at least two different outputs that are operatively coupled to different battery banks.

It would be desirable to provide a controller having improved flexibility in charging, which is capable of receiving two or more input sources, charging battery banks of differing types, and prioritizing available power sources to charge the battery banks simultaneously or to charge the battery banks independently.

The information included in this Background section of the specification, including any references cited herein and any description or discussion thereof, is included for technical reference purposes only and is not to be regarded as subject matter by which the scope of the invention is to be bound.

### SUMMARY

The present application discloses one or more of the features recited in the appended claims and/or the following features which alone or in any combination, may comprise patentable subject matter.

Present embodiments provide a power controller which has connection with at least two power sources. The controller can prioritize based on the power sources available and/or availability of power from the power sources available, charging of at least two battery banks. Notably, the at least two battery banks can be charged simultaneously from the at least two power sources, independently from the at least two power sources, or from each other. In various implementations, this controller may be used on vehicles that can operate continuously (up to 24 hours per day) and the batteries will be charged and discharged very frequently. In other implementations, the controller may be used in other environments that operate continuously (e.g., industrial environments, off-the-grid environments, etc.) where the batteries will be charged and discharged very frequently. As a result, the controller may be switching from one battery or battery bank to another battery or battery bank and actively charging the battery banks at a much higher duty cycle than other applications.

According to some embodiments, a power controller may comprise a circuit board disposed within a housing, at least two power inputs communicatively coupled with the circuit board, each of the at least two power inputs being communicatively coupled with first and second power sources. At least two power outputs communicatively coupled with the circuit board, each of the at least two power outputs communicatively coupled with at least one battery. The circuit board comprising a switch wherein the switch utilizes one or more of the at least two power inputs to simultaneously charge one or more of the at least two power outputs.

The following optional features may be used alone with the power controller or in combination with other features and the power controller. One of the at least two power inputs being one of an alternator, a battery, a solar photovoltaic panel, or any array of solar panels, or a rotating turbine energy source. The alternator may be a dumb alternator or a smart alternator. The circuit board may be capable of prioritizing one of the at least two power inputs based on characteristics of each of the at least two power inputs. The at least one battery may comprise at least a first battery bank and a second battery bank. Each of the first battery bank and the second battery bank may comprise the at least one battery. The first battery bank may comprise a first type. The second battery bank may comprise a second type. The first type and the second type may differ or may be the same type. The first battery bank and the second battery bank may differ in voltage. The power controller may be mounted in a recreational vehicle or trailer thereof, a delivery vehicle or trailer thereof, a transport vehicle or trailer thereof, a service vehicle or trailer thereof, a work vehicle or trailer thereof, a heavy-duty piece of equipment, or a marine craft.

In some embodiments, a method of controlling powering may comprise the steps of providing a controller having a first power input and a second power input, determining by the controller which of the first power input, the second power input, or a combination to utilize, switching, by the controller, between either of the first power input, the second power input, or combining the power inputs by the determining, selecting, by the controller, one of a first battery bank, a second battery bank, or a combination of the first and second battery banks to charge, and causing, by the controller, one or more of the battery banks to charge based on the selecting.

The following optional features may be used alone with the method of power control or in combination with other features and the method of power control. The method may further comprise providing the first power input and the second power input in at least one form of alternator, battery, solar photovoltaic panel, or rotating turbine energy source. The method may further comprise providing the first battery bank and the second battery bank of a single type. Alternatively, the method may further comprise providing the first battery bank and the second battery bank of differing types. The method may further comprise prioritizing which of the first power input, the second power input, or both, to charge the first battery bank or the second battery bank or both the first battery bank and the second battery bank. The method may further comprise mounting the controller in a recreational vehicle or trailer, a delivery vehicle or trailer, a transport vehicle or trailer, a service vehicle or trailer, a work vehicle or trailer, a heavy-duty piece of equipment, or a marine craft.

In some further embodiments, a method of controlling powering may comprise the steps of providing a controller communicatively coupled to at least two battery banks defined by at least a first battery bank and a second battery bank, determining, by the controller, which of the first and second battery banks to utilize as an input for charging an other of the at least two battery banks, selecting, by the controller, the other of the at least two battery banks to charge, causing, by the controller, at least one of the at least two battery banks to charge at least one the other of the at least two battery banks based on the selecting.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. All of the above outlined features are to be understood as exemplary only and many more features and objectives of the various embodiments may be gleaned from the disclosure herein. Therefore, no limiting interpretation of this summary is to be understood without further reading of the entire specification, claims and drawings, included herewith. A more extensive presentation of features, details, utilities, and advantages of the present invention is provided in the following written description of various embodiments of the invention, illustrated in the accompanying drawings, and defined in the appended claims.

### BRIEF DESCRIPTION OF THE FIGURES

In order that the embodiments may be better understood, embodiments of a power controller will now be described by way of examples. These embodiments are not to limit the scope of the claims as other embodiments of a power controller will become apparent to one having ordinary skill in the art upon reading the instant description. Non-limiting examples of the present embodiments are shown in figures wherein:

FIG. 1 is a top view of a power controller wherein the power controller may comprise a housing with at least one circuit board therein;

FIG. 2 is a schematic diagram of the power controller being utilized in a motorized recreational vehicle (RV);

FIG. 3 is a schematic diagram of the power controller being utilized in a heavy-duty tractor trailer;

FIG. 4 is a front view of an example remote display which may be used with the power controller to allow user input and provide information to the user;

FIG. 5 is a schematic view of an example of a controller circuit; and,

FIG. 6 is a line graph which shows various charging stages that are capable with use of the controller;

FIG. 7 is a first flow chart depicting a method of operation; and,

FIG. 8 is a second flow chart which depicts the use of one battery bank input to charge the other of a battery bank.

### DETAILED DESCRIPTION

It is to be understood that a power controller is not limited in its application to the details of construction and the arrangement of components set forth in the following description or illustrated in the drawings. The described embodiments are capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted,” and variations thereof herein are used broadly and encompass direct and indirect connections, couplings, and mountings. In addition, the terms “connected” and “coupled” and variations thereof are not restricted to physical or mechanical connections or couplings.

Reference throughout this specification to “one embodiment”, “some embodiments” or “an embodiment” means that a particular feature, structure, or characteristic described in connection with the embodiment is included in at least one embodiment of the present invention. Thus, appearances of the phrases “in one embodiment”, “in some embodiments” or “in an embodiment” in various places throughout this specification are not necessarily all referring to the same embodiment but may. Furthermore, the particular features, structures or characteristics may be combined in any suitable manner, as would be apparent to one of ordinary skill in the art from this disclosure, in one or more embodiments.

As used herein, the term “communicatively coupled” means that coupled components are capable of exchanging data signals and/or electric signals with one another such as, for example, electrical signals via conductive medium, electromagnetic signals via air, optical signals via optical waveguides electrical energy via conductive medium or a non-conductive medium, data signals wirelessly and/or via conductive medium or a non-conductive medium and the like.

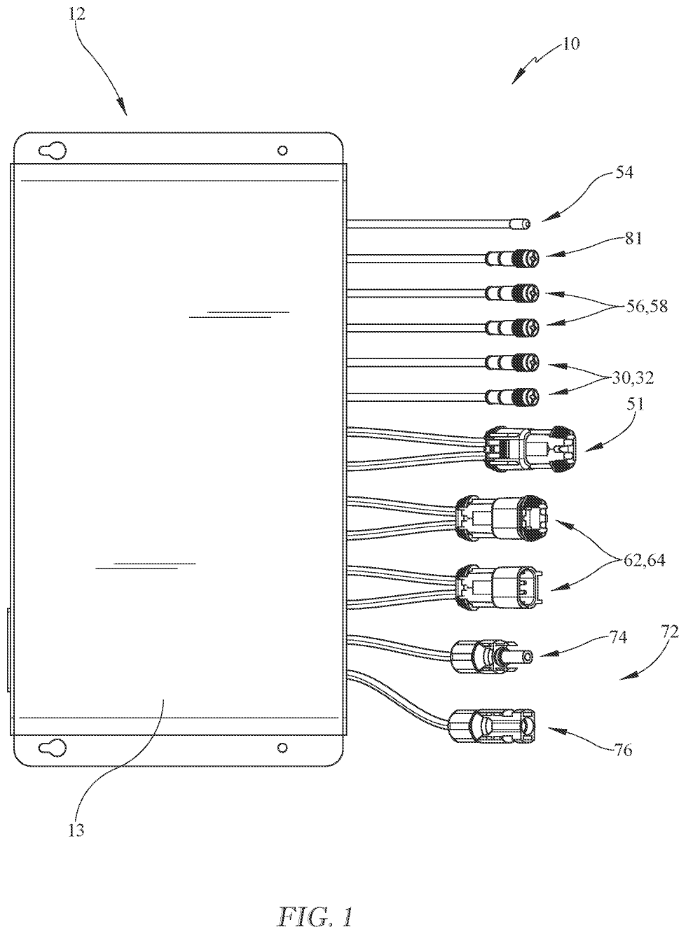

With reference to FIGS. 1-8, embodiments of a power controller are provided which manages two or more power input sources and can charge two or more outputs, such as battery banks. The power controller can prioritize and determine which input to use, or both, and charge battery banks of same or differing types. This provides great flexibility in power management when multiple input sources are available.

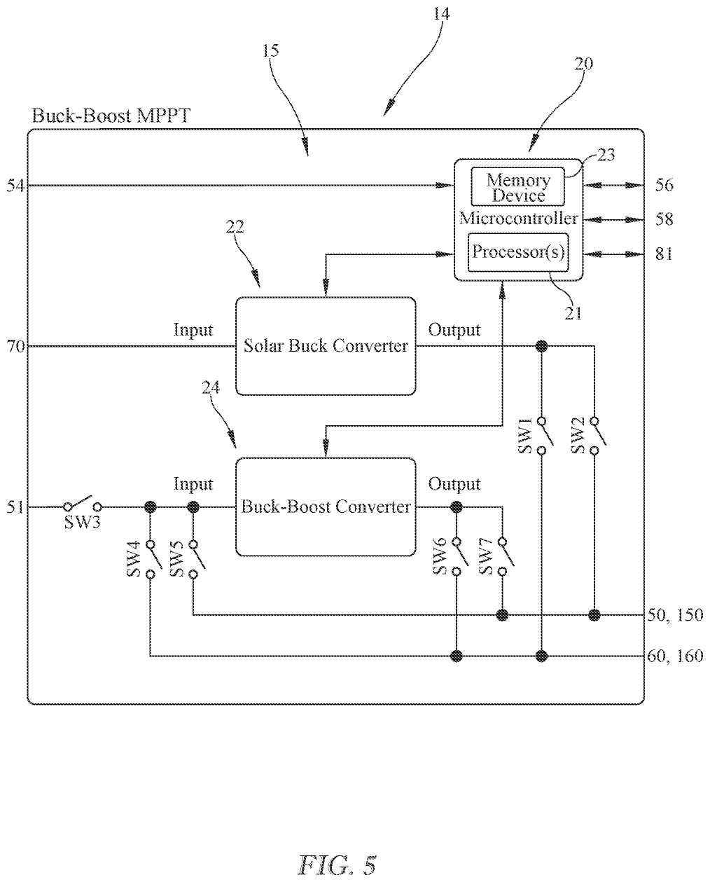

Referring now to FIG. 1, a top view of an example power controller 10 is depicted with various connections. The power controller 10 may comprise a circuit board 14 (FIG. 5) with on-board programming in memory. Example circuit board may include, without limitation, a printed circuit board, stripboard, perfboard, breadboard, and the like. Further, the at least one circuit board may include a sandwich structure of conductive and insulating layers where each of the conductive layers may include a pattern of traces, planes and other features etched from one or more sheet layers of copper, or other conductive material, that may be laminated onto and/or between sheet layers of a non-conductive substrate. Further, the one or more circuit boards may be single-sided, double-sided, multilayer, rigid, flexible, rigid-flex, combinations thereof, and the like. The plurality of various connections are extending from a housing 13.

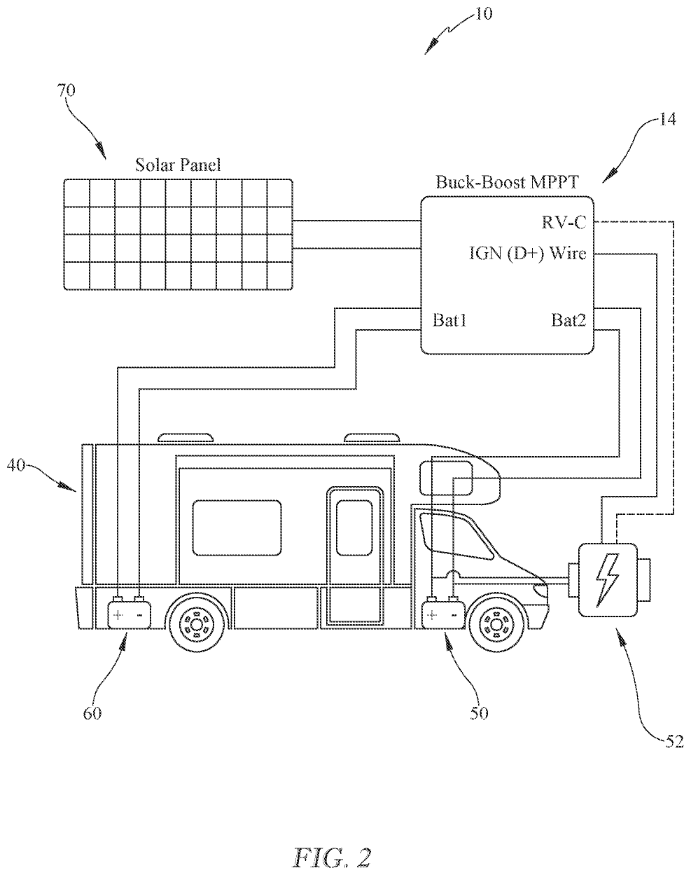

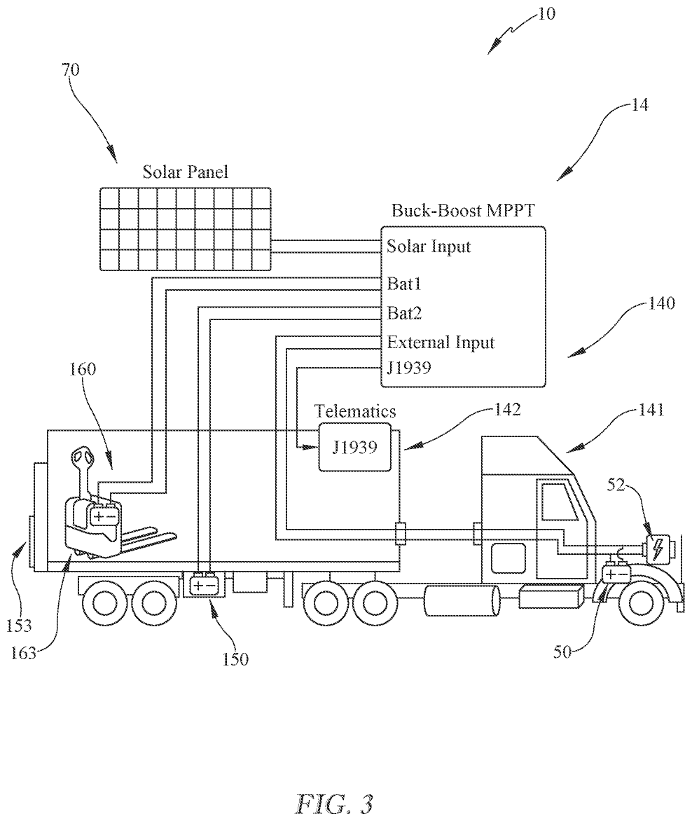

The power controller 10 may be used with various devices or environments, or both, which use a power input to provide power output to charge two or more battery banks 50, 60 (FIG. 2) for example. The term battery bank may include one or more batteries, in other words, each battery bank may include one or more batteries, but are distinct from one another. The first and second battery banks 50, 60 may be used to start the engine of the vehicle 40, 140 (FIGS. 2, 3), starter battery or starter battery bank 50, or may be used to power auxiliary devices, house battery or house battery bank 60. Although the first and second battery banks 50, 60 depicted in FIGS. 2 and 3 are integral to the vehicles 40, 140 depicted in FIGS. 2 and 3, it should be understood that is for sake of example and is not meant to be limiting. For example, the first and second battery banks 50, 60 (and/or other battery banks) can be utilized in other environments, such as industrial environments, marine environments and/or off-the-grid environments.

Each battery bank 50, 60, 150, 160 (FIGS. 2, 3) may comprise a single battery type and all the battery banks 50, 60 may be the same type or differing types. The types of battery banks may include, for example, GEL battery banks, AGM battery banks, flooded battery banks, Lithium (LiFEPO₄) battery banks, and/or other types of battery banks. This list of battery banks is not exhaustive but merely illustrative of examples.

The controller 10 may be utilized in mobile solutions, for example recreational vehicles, heavy-duty tractor trailers, service vehicles or trailer thereof, a work vehicle or trailer thereof, heavy duty equipment, or a marine craft. The controller 10 may also be used at other fixed installations such as off-grid camp sites, for example. Additionally, or alternatively, the power controller 10 may be used in fixed solutions in which there are multiple input sources and two or more battery banks to be charged for utilization. Any of these may comprise multiple input power sources and may be used to charge battery banks.

The controller 10 may receive power inputs from various input sources. The various input sources can include, for instance, renewable energy sources and/or non-renewable energy sources. For example, in some embodiments, the controller 10 may receive power from an alternator 52 (FIG. 2, 3) of the vehicle 40, 140, from a first battery bank 50, such as a starter battery or battery bank, as non-renewable energy sources. Additionally, or alternatively, the controller 10 may receive power from one or more solar (photovoltaic) panels 70 of the vehicle 40, 140, from a rotating turbine power source (not shown), such as a wind or hydro turbine, and/or from other renewable energy sources, as renewable energy sources. One skilled in the art should recognize that multiple solar panels 70 may be used and are often referred to as an array. All these input sources are direct current (DC) sources. This list is not exhaustive and various alternate energy sources may be utilized.

At one end of a housing 12, an ignition signal input 54 extends into the controller 10. The ignition signal input 54 provides a signal from the alternator 52 on a vehicle engine, such as a truck, RV, or marine craft. The controller 10 may operate with various types of alternators. In the simplest form, a “dumb” alternator charges when the engine is running. A traditional alternator attempts to maintain a fixed voltage, usually 13.2V-16V, when charging. When used with a “dumb” alternator, the controller 10 will have no way to determine if the alternator 52 is charging other than measuring the voltage. For example, the alternator may be considered to be charging the starter battery if the voltage is greater than 13.2V. Put another way, these dumb alternators may not utilize the ignition signal input 54, and the ignition signal input 54 may be omitted in implementations where the alternator is a dumb alternator.

In contrast with dumb alternators, there are also “smart” forms of alternators. Smart alternators are more intelligent in that they can adjust their voltage and current output and may be accomplished by utilizing a regulator that is either internal or external to the alternator. In a first form of a smart alternator, the regulator is enabled using the ignition signal input 54 (e.g., “IGN” or “D+” in FIG. 5) that is 12V when the vehicle ignition is turned on and 0V when the vehicle ignition is turned off. The controller 10 may use this ignition signal input 54 to determine if the alternator is currently charging or not. The controller 10 may monitor whether the alternator 52 is charging based on whether there is a non-zero signal ((or near non-zero) e.g., +/−0.5V), and determine the alternator 52 may charge the second battery bank 60, the house battery for example in response to determining that there is a non-zero signal. In this first smart form, the ignition signal input 54 may be used to communicate between the alternator 52 and the controller 10. The ignition signal wire is shown in a bare wire form which may be coupled to a wire extending from the alternator 52, or alternatively may represent a single wire extending between the alternator 52 and the controller 10.

In a second form of a smart alternator, the controller 10 can provide variable output voltage and may include a communication protocol to communication with the controller, for example RV-C, CANBUS, Modbus, or J1939, as some non-limiting examples. In this second smart form, the alternator 52 can be coupled to, for instance, an RV-C charger device that can communicate with the controller 10. The controller 10 may use RV-C to determine if the alternator 52 is enabled and thus available as a charging source. If the determination is made that the alternator 52 is available, it may be used as a directed charger in the form of a power input source in the same or similar manner described above.

In any of these types of alternators, the controller 10 may receive a signal and power which may be directed to charge output battery banks 50, 60 (FIG. 2) for example. The first and second battery banks 50, 60 of the embodiments are also direct current (DC) devices.

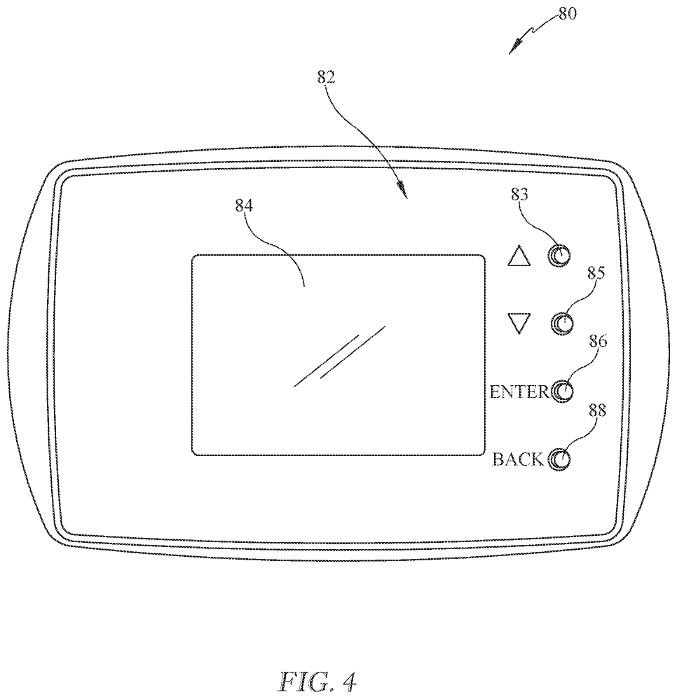

The controller 10 may also comprise a remote display port 81. The controller 10 may have an input and user interface in the form of a remote display 80 (FIG. 4). The remote display 80 may provide the user voltage read outs for the battery banks 50, 60 or for the at least one solar panel 70 (FIG. 2) for example, or other information. The remote display 80 may receive data from the remote display port 81 of the controller 10 as well as provide user input from the remote display 80 to the controller 10. At the controller 10, in one non-limiting example, a 3-pin IP68 connector may be utilized for connection and communication.

Also shown on the controller 10 are RV-C port 56 and J1939 port 58. The RV-C port 56 and J1939 port 58 are communication ports for the controller 10 and may be used to communicate with, for example, “smart versions” of alternators 52 either in RV communication standards or trucking communication standard in the case of the J-1939 port 58. In some non-limiting examples, the controller 10 may comprise wires with 2-pin IP68 connectors.

The controller 10 may also have temperature sensor ports 30, 32 to measure temperatures of the battery banks 50, 60, respectively. In various implementations, a temperature of the battery banks 50, 60 may influence when and/or how the battery banks 50, 60 should be charged. For example, when charging lead-acid batteries, there is a desire to perform temperature compensation and adjust voltage during the charging in response to battery temperatures and high/low temperature limits to prevent the battery from being overcharged. Accordingly, the controller 10 can use various techniques to achieve temperature compensation. For instance, the controller 10 can use a temperature compensation factor to adjust the charging current according to the measured temperature of the lead-acid battery to ensure there is no damage to the lead-acid battery. Notably, this temperature compensation technique may be used in charging lead-acid batteries but not some other batteries such as lithium batteries. Likewise, when charging lithium-ion batteries, there is a desire to not charge them when the temperature is near or below freezing (e.g., near or below 0 degrees Celsius or 32 degrees Fahrenheit). Thus, with the temperature sensor ports 30, 32, a temperature of each of the battery banks 50, 60 may be provided to the controller, and charging may be altered for improved conditioning of the battery banks 50, 60, and prolonging life of the battery banks 50, 60. In the non-limiting examples, the temperature sensor ports 30, 32 may comprise 2-pin IP68 connectors for the temperature communication signals to the controller 10 and operatively coupled to a corresponding to one of the battery banks 50, 60.

In some other embodiments, the sensor ports 30, 32 may be voltage sensors. For example, in some embodiments, one port may be for external input to measure the actual voltage at the source and one may be to measure battery voltage at one of the batteries.

With regard to the external input voltage sensor, the wires between the controller 10 and the source can be up to 60 feet long. The source is the alternator from the tractor, but the place where the controller 10 receives this power may be a 7-way connector that connects the tractor to the trailer in a semi-truck application. Further, these same wires may be used to control the brakes for the trailer and it may not be desirable to take power from here unless the voltage is above a configurable threshold or else the brakes may not work properly. Accordingly, we need to be able to measure this accurately.

The second voltage measurement may be used for one of the battery voltages, and the controller 10 may also be configurable to select which battery in some embodiments. The purpose here is to obtain an accurate voltage measurement in case the battery is located far from the controller 10, which might be the case in some semi-truck applications where the pallet jack is at the back of the trailer and the controller 10 is at the middle or front of the trailer, or, in an RV application, where the controller 10 is located at the back of the RV and the starter battery is located at the front, which could be a distance of up to 60 feet as well. One skilled in the art will recognize the voltage drop concerns in these long wire runs.

The controller 10 further comprises an external power input 51. The external power input 51 may for example be communicatively coupled with the controller 10 for switching and guiding power and other electrical signals to either or both of at least two battery banks 50, 60. In some examples, the external power input 51 may be, for example, the alternator 52 of a vehicle 40, 140 (FIGS. 2, 3), a starter battery bank 50 from a tractor, or an engine of an alternative vehicle such as marine craft, or an alternative source such as a rotating turbine of various types—wind power, hydropower, and/or other rotating turbines. In some embodiments, the first battery bank 50 may be the starter battery and may be charged from the alternator, and in some embodiments may also be charged by way of input to controller 10 and connection to the starter battery. In other embodiments, for example, the first battery bank may be located in a trailer of a tractor trailer, as shown in FIG. 3 and described further herein.

The controller 10 further comprises battery outputs 62, 64 which direct power from the controller 10 to the two or more battery banks 50, 60 based on decisions made and processes occurring at the controller 10. The battery outputs 62, 64 can also function as power inputs, despite the names in this description, to facilitate transfer of power between battery banks 50, 60, 150, 160 to manage power when there is no external input 51 or solar power input 72 available. Thus, while the term output is used for elements 62, 64, one skilled in the art will understand based on this teaching that the elements may also function as inputs during some configurations of operation.

Finally, the controller 10 may further comprise an auxiliary input 72. In some non-limiting examples, the auxiliary input 72 may be a DC input defined by a solar input and is depicted in the non-limiting example as first and second ports 74, 76. The solar input may be provided by one or more solar panels 70 (FIG. 2). However, it should be understood that is not meant to be limiting and that the auxiliary input 72 may be configured for various other types of inputs from various other sources as described herein.

While the example embodiment shows two inputs 51, 72 and two outputs 62, 64 various numbers may be utilized for either the input and the output. The number of inputs and outputs may or may not correspond to one another. For example, the controller 10 may use power from input 51 or input 72, or both, to charge battery 62 or battery 64, or both. Similarly, if there are more than 2 inputs the controller 10 may use input 1 or input 2 or input 3 or any combination of those inputs to charge battery bank 1 or battery bank 2 or battery bank 3 or any combination of battery banks. To be clear, there also may be differing numbers of inputs and outputs, for example 3 inputs and 5 outputs. However, the example number of inputs and outputs is not limiting.

Referring now to FIGS. 2 and 3, two non-limiting examples of installations are provided and individually described herein. According to a first example of FIG. 2, a recreational vehicle (RV) application is shown schematically. A vehicle 40 is embodied by the (RV) in this example. The recreational vehicle 40 may be a motorhome which comprises an engine to propel the vehicle.

The RV 40 is shown with a schematic the first battery bank 50 embodied as the starter battery, which is shown near the engine area at the front of the RV 40. A second battery bank 60 is also shown schematically at the rear of the RV 40 and represents a house battery bank in this embodiment. The house battery bank 60 may be used to power air conditioners, fans, internal cabin lights, pumps for clean water and waste, television, stereo, and the like. The controller 10 is shown adjacent to the RV 40 and with representative electrical conduits extending between the controller 10 and various other structures of the RV.

Additionally, the alternator 52 shown spaced from the RV 40, also provides power to the controller 10. The controller 10 may be connected by the ignition signal input 54, and/or the RV-C port 56 depending on the type of alternator 52 being used. The alternator 52 is shown connected directly to the first battery bank 50 but is also connected to the second battery bank 60 indirectly by way of the controller 10. Thus, in this embodiment, the alternator 52 may charge both of the first battery bank 50 and the second battery bank 60.

The figure also depicts a solar panel 70 that is communicatively coupled to the controller 10. The solar panel 70 may be one or more panels defining an array and provides the at least one power source input 72 (FIG. 1) to the controller 10. The solar panel 70 and alternator 52 provide power inputs 72, 51 to the controller 10 and the controller 10 provides power outputs 62, 64 (FIG. 1) to the house battery bank 60 and the starter battery bank 50.

With this arrangement, the controller 10 provides for parallel charging with simultaneous use of the solar panels 70 and the alternator 52. Additionally, the controller 10 may include prioritization based on conditions of the alternator 52, the solar panel 70, and the battery banks 50, 60. For example, the controller 10 may monitor current and/or voltage and if the current rating does not reach a desired maximum, from the at least one solar panel 70, then the alternator 52 may additionally be used to charge the second (house) battery bank 60.

Referring now to FIG. 3, the controller 10 is shown in use with a second type of vehicle 140, for example a tractor trailer represented schematically. The vehicle 140 comprises a tractor 141 which includes an engine that pulls a trailer 142 and that is mechanically coupled to the tractor 141. In the depicted embodiment, the tractor 141 is shown with a starter battery bank 50 and an alternator 52. The controller 10 is shown spaced from the tractor trailer 142 and may be located on the tractor 141 or the trailer 142. The trailer 142 may have two battery banks 150, 160. In the example the first battery bank 150 is for a lift gate 153 at the rear of the trailer 142. The second battery bank 160 may be for a pallet jack 163 in the rear of the trailer 142 which moves material therein.

A solar panel 70 is also shown adjacent the tractor trailer 142 and may be one or more panels forming an array. For example, these may be located on an upper surface of the trailer 142, or on any upper surface of the tractor 141. The solar panel 70 provides a power input 72 to the controller 10 as in the previous embodiment. The alternator 52 and the starter battery bank 50 may also provide an external power input 51 to the controller 10. The controller 10 outputs power to the lift gate battery (first battery bank 150) bank and the pallet jack battery (second battery bank 160) bank.

The controller 10 can prioritize between the alternator 52 and the solar panel 70 to charge the battery banks 50, 150, 160 in the trailer 142. The controller 10 can charge the battery banks 50, 150, 160 with one of, or both of, the alternator 52 and the solar panel 70.

This embodiment also provides another advantage which will become apparent to one skilled in the art upon review of this description. In the depicted example, the first battery bank 150 is 12 Volt, and the second battery bank 160 is 24 Volt. The alternator 52 may operate at 12 volts in the example. The controller 10 however may boost the alternator voltage to 24 volts for charging the second (pallet jack) battery bank 160.

An additional advantage provides that the controller 10 may compensate for voltage drop due to long wire runs in the trailer 142.

Referring now to FIG. 4, a remote display 80 is shown in a front view. In some embodiments, the remote display 80 may comprise a housing 82 and a display 84. In some examples, the display 84 may be a liquid crystal display (LCD), a light emitting diode (LED) display, organic light emitting diode (OLED) display, or other display which allows the remote display 80 to provide information to the user.

The remote display 80 may also comprise input buttons 83, 85, 86, 88, either physical buttons or virtual that appear on the display 84. For example, the buttons may comprise in some embodiments an enter button 86 to make selections, including movement in a forward direction through menus, a back button 88 to move in reverse through the menus, as well as up and down input buttons 83, 85 to move through menu selection options. Generally, the input buttons 83, 85, 86, 88 allow a user to make selections and move through menus.

The remote display 80 may also have a connector for communication with the controller. For example, the remote display 80 may in communication with the controller 10 through a communication protocol, for example Modbus. The remote display 80 may include as a non-limiting example, an RJ12 connector on the rear of the remote display 80.

The remote display 80 may provide various bits of information. In some embodiments, the controller 10 may provide the following information to the user by way of the remote display 80: controller temperature, the rated voltage, the rated charging current, and specific information about the controller hardware, software, model and serial numbers, for example. Additionally, the remote display 80 may provide additional information about the solar panel 70, for example, solar panel voltage and solar panel current. Further, the remote display 80 may provide battery information to the user for each of the battery banks 50, 60, 150, 160, for example, charging state, voltage for each battery bank, current for each battery bank, and temperature for each battery bank. These lists are not exhaustive and instead are merely exemplary of information that may be provided to the user by the remote display 80.

The remote display 80 may also display to the user historical information from the controller 10. The historical data may be stored in a data storage device , which may generally be a storage medium, may contain one or more data repositories for storing data that is received and/or generated. The data storage device may be any physical storage medium, including, but not limited to, a hard disk drive (HDD), memory, removable storage, and/or the like. For a non-limiting example, the historical data may include amp-hour information for one or more time periods from solar power input 72, and from the external input 51, such as from the alternator 52 for example, to each of the first battery bank 50, 150 and second battery bank 60, 160, for example. Additionally, total number of operating days, cumulative solar power generation and cumulative external input power generation all may be recorded for possible display on the remote display. These lists are not exhaustive.

The remote display 80 is also capable of displaying fault conditions to the user. The fault conditions may include but are not limited to the following: solar panel reverse polarity, solar panel over voltage, solar panel short, external input reverse polarity, external input over voltage, external input short circuit, and/or controller over temperature. Further, the following are examples of fault conditions that may be displayed to the user for each battery bank 50, 60, 150, 160: short circuit, under voltage, over voltage, over temperature, under temperature.

Referring now to FIG. 5, a schematic representation of the controller 10 is shown. The circuit 15 is a referred to as a buck-boost maximum power point tracking (MPPT) converter. The buck—boost converter is a type of DC-to-DC converter that has an output voltage magnitude that is either greater than or less than the input voltage magnitude. MPPT is a technique to regulate the charge of a battery bank and more specifically is an electronic DC to DC converter that optimizes the match between the solar array (PV panels), and the battery bank. In some forms the MPPT converter converts a higher voltage DC output from solar panels (and for example wind generators) down to the lower voltage needed to charge batteries.

The controller 10 comprises the at least one circuit board 14 and may include a microcontroller 20 including a memory device 23, such as non-volatile and/or a volatile computer-readable medium and, as such, may include random access memory (including SRAM, DRAM, and/or other types of random access memory), read only memory (ROM), flash memory, registers, compact discs (CD), digital versatile discs (DVD), and/or other types of storage components. The memory device 23 of the microcontroller 20 may include one or more programming instructions thereon that, when executed, for example by one or more processors 21 of the microcontroller 20, cause the one or more processors 21 of the microcontroller 20 to perform any operations described herein with respect to the controller 10. The microcontroller 20 and/or the one or more processors thereof may be a computer processing unit (CPU), computing device, or combinations thereof. As such, the one or more processors 21 may include any processing component configured to receive and execute instructions (such as from the data storage device and/or the memory device). The programming instructions stored on the memory device 23 may be embodied as a plurality of software logic modules, where each logic module provides programming instructions for completing one or more tasks, as described in greater detail with respect to the controller 10.

The microcontroller 20 may have communication with the RV-C and J1939 ports, as well as the remote display port 81 to provide display data to the remote display 80 (FIG. 4). The microcontroller 20 may also have communication with the ignition signal input 54 from the alternator 52 in embodiments which utilize a smart alternator. While a single printed circuit board 15 is shown schematically, it is possible that there might be more than one circuit board contained in the housing. For example the digital and power circuits maybe separated to help reduce the effects of electrical noise from the power components on the digital components. In another example, one printed circuit board may handle power conversion while a second printed circuit board may be used to convert from modbus to RV-C for communications. Various configurations are capable of use and therefore the example single printed circuit board should not be considered limiting.

The microcontroller 20 is also in communication with a solar buck converter 22. The solar buck converter 22 comprises input for power from the at least one solar panel 70 and provides output to the circuit to the battery banks 50, 60, 150, 160.

The controller 10 also comprises a buck-boost converter 24 which communicatively coupled with the microcontroller 20. The buck-boost converter 24 is communicatively coupled with the external power input 51, for example the alternator 52 in some embodiments. The external power input 51 is shown as being in direct communicatively coupled with the battery banks 50, 60, 150, 160 or alternatively, with the buck-boost converter 24 and thereby indirectly with the first and second battery banks 50, 60, 150, 160.

As can be seen from the circuit as a whole, the external power input 51 and solar panels 70 pass through the circuit 15 and the one or more switches provide switching configurations and various options, as controlled by the microcontroller 20, to charge the first and second battery banks 50, 60, 150, 160. The options provide for simultaneous input sources which may be prioritized based on availability of the sources and conditions of the battery banks 50, 60, 150, 160.

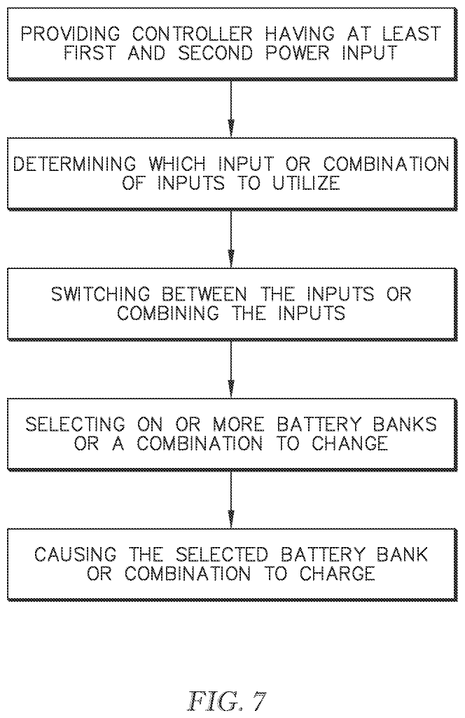

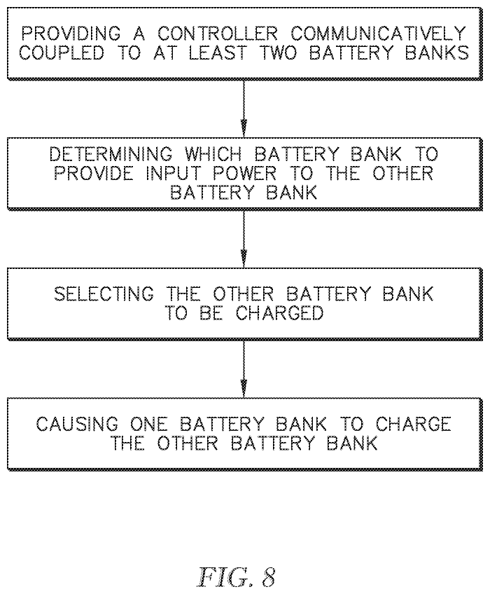

As can be understood from review of the circuit 15, and in view of the flow charts of FIGS. 7 and 8, the controller 10 provides for variations of charging capabilities by selection of inputs and/or outputs via one or more switches. For example, the first battery bank 50, 60, 150, 160 or the second battery bank 50, 60, 50, 160 may be charged from the solar panel 70. The first battery bank may charge the second battery bank and vice-versa. The first battery bank may be charged by the second battery bank and solar panel 70, or alternatively, the second battery bank may be charged by the first battery bank and the solar panel 70. The first battery bank may be charged by the external power input 51 or alternatively the second battery bank may be charged by the external power input 51. Still further, the first battery bank may be charged by the external power input 51 and the solar panel 70 or alternatively the second battery bank may be charged by the external power input 51 and the solar panel 70. In still a further configuration, the second battery bank may be charged from the external power input 51 and the first battery bank may be charged from the solar panel 70. Moreover, it should be understood that additional input and/or output ports may be added for use in charging additional, or alternative, battery banks.

The controller 10 allows for prioritization based on characteristics of the inputs, the outputs, combinations, or other factors. While the characteristics may vary, and some of them have been described, one non-limiting and non-exhaustive example is provided herein. The controller 10 may try to use solar power input 72 in priority to charge the battery banks 50, 60, 150, 160 by first using solar power panel 70, if available, to charge. In this example we will consider a 30 A maximum current, however this is merely an example and other maximum currents may be utilized, for example 50 A or 100 A, or others. In this example, if a maximum of 30 A current is achieved, the controller 10 will continue to use solar power panel 70 and input 72 as the sole power source to charge. If on the other hand the 30 A current cannot be achieved, the controller 10 will continue to use all available input power from solar panel 70 via input 72 but will try to supplement this power with the external input power 51. For example, if 20 A is available from the at least one solar panel 70 is available then the controller 10 will use 10 A from the external input 51 for a total of 30 A to the battery bank or battery banks being charged. If there is no power available on the external input 51 the controller will look for alternator power using the ignition signal input 54 to determine if there is an alternator charging battery 62. If the ignition signal input 54 indicates there is an alternator 50 the controller 10 will continue to use all available input power from the at least one solar panel 70 but will try to supplement this power with the input power from output 62 to charge via output 64. If ignition signal input 54 does not indicate there is an alternator charging, the controller 10 will look at the battery bank voltage on battery output 62 to determine if there is a dumb alternator charging battery 62. If the voltage is above 13.2V (which could also be a different voltage, this is a configurable parameter) then the controller will assume there is an alternator charging battery at output 62 and will use battery output 62 as an input to charge battery 64 in supplement with solar power to achieve maximum output current. The above priority also holds true if there is no solar power. For example, if the available solar power is OA then the controller will first look to the external input 51 for power to charge the batteries at maximum current of 30 A (or 50 A or 100 A), then ignition signal input 54 to determine if it can take power from battery output 62 to charge via battery output 64 at maximum current of 30 A (or 50 A or 100 A for example), then to the voltage on battery 62 to determine the same. For the above priority sequence, the input sources are continuously monitored so the controller 10 can adapt to any changes in the amount of available power from each input source. It should also be noted that this priority sequence has been chosen specifically for RV and semi-truck applications, but other applications may require a different priority sequence, this is only an example of what the technology is capable of

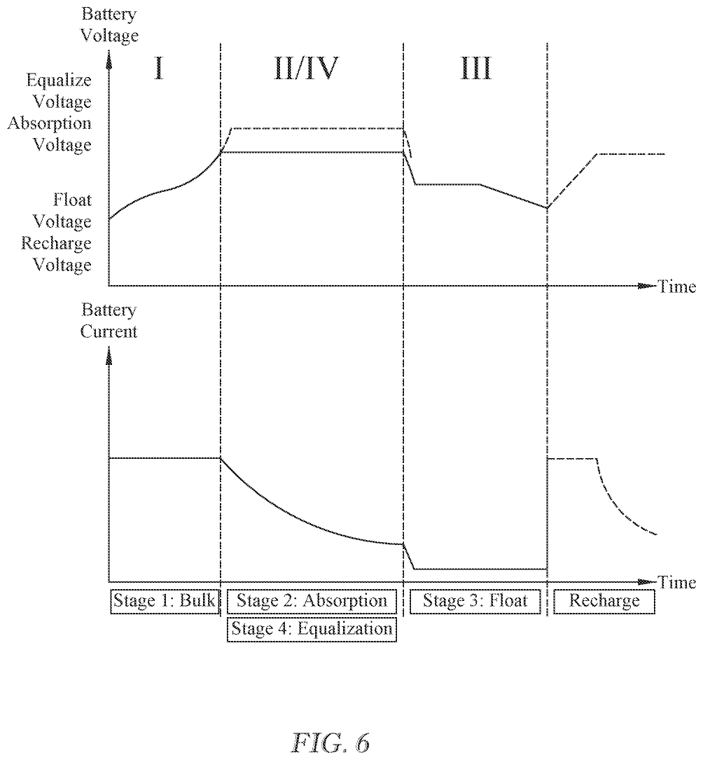

Referring now to FIG. 6, line graphs are provided comparing battery bank voltage to time and battery bank current to time. In some embodiments, the battery banks may be provided with four charging stages by the controller. The four stages provide rapid, efficient, and safe charging. The four stages are bulk charging (I), absorption charging (II), float charging (III) and equalization charging (IV).

In the first stage, bulk charging (I), the controller 10 uses 100% of the available power to recharge either or both battery banks 50, 60, 150, 160. As shown in the current graph, the current is constant in the bulk charging stage, but the battery bank voltage has not yet reached constant voltage. In this mode, the controller provides constant and maximum current to either or both of the battery banks.

In the second stage, absorption charging (II), when a battery bank 50, 60, 150, 160 reaches the constant voltage set point, the controller 10 begins to operate in constant voltage charging mode. When the battery reaches the bulk-absorption set point, the controller will start to operate in the absorption stage. Thus, the absorption charging (II) is no longer bulk charging (I), and the current may gradually drop. The absorption duration is the amount of time the bulk-absorption voltage will be applied to the battery bank during the absorption stage.

In the third stage of charging, float charging (III), following the constant voltage mode, the controller 10 may reduce the battery voltage to a float voltage set point. Once the battery bank is fully charged, there will be no more chemical reaction. Instead, all of the charge current turns to heat or gas. As a result, the controller 10 reduces the voltage charge to smaller quantity, while lightly charging the battery bank. The float charge mode offsets power consumption while maintaining a full battery storage capacity. When a load drawn from either battery bank exceeds the charge current, the controller 10 will no longer be able to maintain the battery bank 50, 60, 150, 160 to a float set point and the controller will end the float charge stage. At this time the controller 10 may return to bulk charging (I).

In a fourth stage of charging, equalization charging (IV), a maintenance process may be carried out periodically. For example, in one default setting, the equalization may occur once every thirty days. The equalization interval is the frequency at which an equalize charge will be performed to maintain the battery. In the equalization charging mode, the battery banks 50, 60, 150, 160 are intentionally overcharged for a period of time. Certain types of batteries benefit from periodic equalizing charge, which can stir the electrolyte, balance battery voltage and complete chemical reaction. Equalizing charge increases the battery voltage, higher than the standard complement voltage, which gasifies the battery electrolyte. The equalize voltage is the voltage setpoint used during an equalize maintenance cycle.

Additionally, after the battery banks are completely charged, the charging cycle completes, and the battery is allowed to slowly discharge until it reaches the charge return voltage. At that point, a new charge cycle if initiated.

While several inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the invent of embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

All definitions, as defined and used herein, should be understood to control over dictionary definitions, definitions in documents incorporated by reference, and/or ordinary meanings of the defined terms. The indefinite articles “a” and “an,” as used herein in the specification and in the claims, unless clearly indicated to the contrary, should be understood to mean “at least one.” The phrase “and/or,” as used herein in the specification and in the claims, should be understood to mean “either or both” of the elements so conjoined, i.e., elements that are conjunctively present in some cases and disjunctively present in other cases.

Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

It should also be understood that, unless clearly indicated to the contrary, in any methods claimed herein that include more than one step or act, the order of the steps or acts of the method is not necessarily limited to the order in which the steps or acts of the method are recited.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

The foregoing description of methods and embodiments has been presented for purposes of illustration. It is not intended to be exhaustive or to limit the invention to the precise steps and/or forms disclosed, and obviously many modifications and variations are possible in light of the above teaching. It is intended that the scope of the invention and all equivalents be defined by the claims appended hereto.

1. A power controller, comprising:
a circuit board disposed within a housing;
at least two power inputs in communicatively coupled with said circuit board, each of said at least two power inputs being capable of communicatively coupled with first and second power sources;
at least two power outputs in communicatively coupled with said circuit board, each of said at least two power outputs in communicatively coupled with at least one battery;
said circuit board comprising a switch wherein said switch utilizes one or more of said at least two power inputs to simultaneously charge one or more of said at least two power outputs.

2. The power controller of claim 1, one of said at least two power inputs being one of an alternator, a battery, a solar photovoltaic panel, or array of solar photovoltaic panels, or a rotating turbine energy source.

3. The power controller of claim 2, said alternator being a dumb alternator or a smart alternator.

4. The power controller of claim 2, said circuit board capable of prioritizing one of said at least two power inputs based on characteristics of each of said at least two power inputs.

5. The power controller of claim 1, wherein said at least one battery comprises at least a first battery bank and a second battery bank.

6. The power controller of claim 5, wherein each of said first battery bank and said second battery bank comprises said at least one battery.

7. The power controller of claim 5, said first battery bank comprising a first type.

8. The power controller of claim 7, said second battery bank comprising a second type.

9. The power controller of claim 8 wherein said first type and said second type differ or are a same type.

10. The power controller of claim 8, wherein said first battery bank and said second battery bank differ in voltage.

11. The power controller of claim 1, said power controller mounted in a recreational vehicle or trailer thereof, a delivery vehicle or trailer thereof, a transport vehicle or trailer thereof, a service vehicle or trailer thereof, a work vehicle or trailer thereof, a heavy-duty piece of equipment, or a marine craft.

12. A method of controlling powering comprising the steps of:
providing a controller having a first power input and a second power input;
determining by the controller which of said first power input, said second power input, or a combination to utilize;
switching, by the controller, between either of said first power input, said second power input, or combining said power inputs by said determining;
selecting, by the controller, one of a first battery bank, a second battery bank, or a combination of said first and second battery banks to charge;
causing, by the controller, one or more of said battery banks to charge based on said selecting.

13. The method of claim 12, further comprising providing said first power input and said second power input in at least one form of alternator, battery, solar photovoltaic panel, or rotating turbine energy source.

14. The method of claim 12 further comprising providing said first battery bank and said second battery bank of a single type.

15. The method of claim 12 further comprising providing said first battery bank and said second battery bank of differing types.

16. The method of claim 12 further comprising prioritizing which of said first power input, said second power input, or both, to charge said first battery bank or said second battery bank or both said first battery bank and said second battery bank.

17. The method of claim 12 further comprising mounting said controller in a recreational vehicle or trailer, a delivery vehicle or trailer, a transport vehicle or trailer, a service vehicle or trailer, a work vehicle or trailer, a heavy-duty piece of equipment, or a marine craft.

18. A method of controlling powering comprising the steps of:
providing a controller communicatively coupled to at least two battery banks defined by at least a first battery bank and a second battery bank;
determining, by the controller, which of said first and second battery banks to utilize as an input for charging an other of said at least two battery banks;
selecting, by the controller, the other of said at least two battery banks to charge;
causing, by the controller, at least one of said at least two battery banks to charge at least one said other of said at least two battery banks based on said selecting.
